(19) United States
(12) Patent Application Publication
(10) Pub. No.: US 2021/0234055 A1
(43) Pub. Date: Jul. 29, 2021

(54) SOLAR CELL MODULES

(71) Applicant: INDUSTRIAL TECHNOLOGY RESEARCH INSTITUTE, Hsinchu (TW)

(72) Inventors: Wen-Hsien WANG, Tainan City (TW); Min-Tsung KUAN, Taichung City (TW); Chiou-Chu LAI, Zhubei City (TW); Hsin-Hsin HSIEH, Taipei City (TW)

(73) Assignee: INDUSTRIAL TECHNOLOGY RESEARCH INSTITUTE, Hsinchu (TW)

(21) Appl. No.: 17/138,198

(22) Filed: Dec. 30, 2020

Related U.S. Application Data
(63) Continuation-in-part of application No. 16/731,711, filed on Dec. 31, 2019.

(30) Foreign Application Priority Data
Dec. 22, 2020 (TW) 109145460

(51) Int. Cl. H01L 31/048; H01L 31/055; H01L 33/50; C09K 11/06

(52) U.S. Cl. CPC H01L 31/0481; H01L 31/055; H01L 33/502; C09K 2211/1018; H01L 2933/0041; C09K 2211/1425; C09K 11/06

(57) ABSTRACT

A solar cell module is provided. The solar cell module includes a first substrate, a second substrate opposite to the first substrate, a cell unit disposed between the first and second substrates, a first thermosetting resin layer disposed between the cell unit and the first substrate, a first thermoplastic resin layer disposed between the cell unit and the first thermosetting resin layer, a second thermosetting resin layer disposed between the cell unit and the second substrate, and a second thermoplastic resin layer disposed between the cell unit and the second thermosetting resin layer, wherein at least one of the first thermoplastic resin layer and the second thermoplastic resin layer contains 0.1% to 10% of light diffusion particles.

### CROSS REFERENCE TO RELATED APPLICATIONS

This application is a Continuation-In-Part of U.S. patent application Ser. No. 16/731,711, filed on Dec. 31, 2019, and claims priority of Taiwan Patent Application No. 109145460, filed on Dec. 22, 2020, the entirety of which is incorporated by reference herein.

### TECHNICAL FIELD

The present disclosure relates to a solar cell module, and more particularly to a disassemblable and recyclable solar cell module with efficiency.

### BACKGROUND

With the recent growth in the popularity of solar cell modules, an increasing number of waste solar cell modules are being generated, causing problems with respect to recycling and resource reuse. In order to recover materials from used solar cell modules, the solar cell modules must first be disassembled.

In order to effectively generate electricity, increase the efficiency and extend the service life of conventional silicon solar module structures, thermosetting polymers such as ethylene vinyl acetate (EVA) or polyolefin (PO) are generally used as packaging materials, to encapsulate and fix polycrystalline or monocrystalline solar cells. Once a cross-linking network occurs among molecules of the thermosetting polymers, neither the glass nor the solar cell panel can be separated by heating and melting the packaging film. As a result, an intact glass or a complete cell panel cannot be got and reused. Therefore, the current conventional method is to smash the module into pieces and burn it, to degrade the packaging film at a high enough temperature to separate the glass from the cell module. One of the difficulties encountered when disassembling conventional silicon solar cell modules is how to remove the thermosetting plastic material so that the glass and the cells can be taken out, recycled, and reused without damaging them.

At present, there are two methods for removing thermosetting plastics. One is to decompose EVA in an acid solution or an organic solvent, and the other is to heat the silicon solar cell module at a temperature of 300° C. to 550° C. to separate the glass plate from the solar cell module. Either method is time-consuming and labor-intensive, and will cause secondary pollution. Therefore, there is an urgent need to solve the above problems by proposing a solar cell module that can maintain the utilization of light energy without increasing the manufacturing process. It is easy to be disassembled and can pass the IEC61215 electrical verification specification to achieve high-value recycling of waste modules in the industry.

Therefore, the development of a disassemblable and recyclable solar cell module with efficiency is desirable.

### SUMMARY

In accordance with one embodiment of the present disclosure, a solar cell module is provided. The solar cell module includes a first substrate; a second substrate opposite to the first substrate; a cell unit disposed between the first and the second substrates; a first thermosetting resin layer disposed between the cell unit and the first substrate; a first thermoplastic resin layer disposed between the cell unit and the first thermosetting resin layer; a second thermosetting resin layer disposed between the cell unit and the second substrate; and a second thermoplastic resin layer disposed between the cell unit and the second thermosetting resin layer, wherein at least one of the first thermoplastic resin layer and the second thermoplastic resin layer contains 0.1% to 10% of light diffusion particles.

A detailed description is given in the following embodiments with reference to the accompanying drawings.

### BRIEF DESCRIPTION OF THE DRAWINGS

FIG. 1 shows a cross-sectional view of a solar cell module in accordance with one embodiment of the present disclosure; and

### DETAILED DESCRIPTION

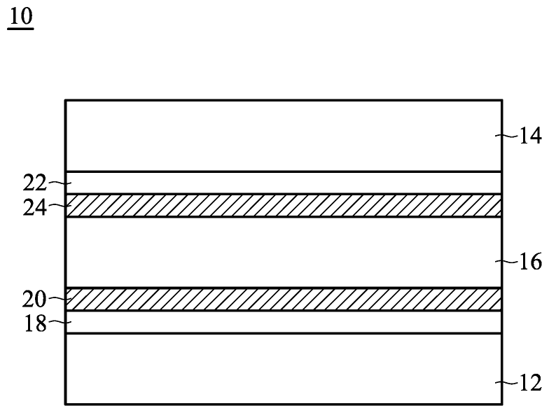

Referring to FIG. 1, in accordance with one embodiment of the present disclosure, a solar cell module 10 is provided. FIG. 1 shows a cross-sectional view of the solar cell module 10.

In FIG. 1, the solar cell module 10 includes a first substrate 12, a second substrate 14, a cell unit 16, a first thermosetting resin layer 18, a first thermoplastic resin layer 20, a second thermosetting resin layer 22 and a second thermoplastic resin layer 24. The second substrate 14 is opposite to the first substrate 12. The cell unit 16 is disposed between the first substrate 12 and the second substrate 14. The first thermosetting resin layer 18 is disposed between the cell unit 16 and the first substrate 12. The first thermoplastic resin layer 20 is disposed between the cell unit 16 and the first thermosetting resin layer 18. The second thermosetting resin layer 22 is disposed between the cell unit 16 and the second substrate 14. The second thermoplastic resin layer 24 is disposed between the cell unit 16 and the second thermosetting resin layer 22. That is, in the disclosed solar cell module 10, the two sides of the cell unit 16 are in contact with the first thermoplastic resin layer 20 and the second thermoplastic resin layer 24, respectively. One side of the first thermosetting resin layer 18 is in contact with the first thermoplastic resin layer 20, and the other side of the first thermosetting resin layer 18 is in contact with the first substrate 12. One side of the second thermosetting resin layer 22 is in contact with the second thermoplastic resin layer 24, and the other side of the second thermosetting resin layer 22 is in contact with the second substrate 14.

In some embodiments, the first substrate 12 and the second substrate 14 may include glass, polyolefin resin or polyester resin, for example, polyethylene (PE), polypropylene (PP) or polyethylene terephthalate (PET).

In some embodiments, the first thermosetting resin layer 18 and the second thermosetting resin layer 22 may include an ethylene vinyl acetate (EVA) copolymer or polyolefin (PO). In some embodiments, when the first thermosetting resin layer 18 and the second thermosetting resin layer 22 include an ethylene vinyl acetate (EVA) copolymer, the weight ratio of vinyl acetate (VA) in the ethylene vinyl acetate (EVA) copolymer is in a range from about 25 wt % to about 35 wt %. In some embodiments, the first thermosetting resin layer 18 and the second thermosetting resin layer 22 further include additives such as a hardening initiator, an antioxidant, a crosslinking agent, or a stabilizer. In some embodiments, the weight ratio of the additives in the first thermosetting resin layer 18 and the second thermosetting resin layer 22 is in a range from about 1 wt % to about 5 wt %.

In some embodiments, the first thermoplastic resin layer 20 and the second thermoplastic resin layer 24 may include diblock hydrogenated styrene-based resin or triblock hydrogenated styrene-based resin. In some embodiments, the first thermoplastic resin layer 20 and the second thermoplastic resin layer 24 may include, but are not limited to, the following copolymers, for example, hydrogenated (styrene-isoprene) diblock copolymers, hydrogenated (styrene-isoprene-styrene) triblock copolymers, hydrogenated (styrene-butadiene-styrene) triblock copolymers, hydrogenated (styrene-isoprene/butadiene-styrene) triblock copolymers, hydrogenated (styrene-ethylene branched isoprene) diblock copolymers, or a combination thereof. In some embodiments, the weight ratio of the styrene block in the diblock hydrogenated styrene-based resin or the triblock hydrogenated styrene-based resin is in a range from about 10 wt % to about 35 wt %.

In some embodiments, the first thermoplastic resin layer 20 and the second thermoplastic resin layer 24 may include diblock acrylic-based resin or triblock acrylic-based resin. In some embodiments, the first thermoplastic resin layer 20 and the second thermoplastic resin layer 24 may include, but are not limited to, the following copolymers, for example, poly(methylmethacrylate-b-isoprene), poly(methylmethacrylate-b-butadiene), poly(methylmethacrylate-b-isoprene-b-methylmethacrylate), poly(methylmethacrylate-b-butadiene-b-methylmethacrylate), poly(methylmethacrylate-b-isoprene/butadiene-b-methylmethacrylate), poly(methylmethacrylate/acrylate/methylmethacrylate), or a combination thereof. In some embodiments, the weight ratio of the methylmethacrylate (MMA) block in the diblock acrylic-based resin or the triblock acrylic-based resin is in a range from about 20 wt % to about 60 wt %. In some embodiments, the weight ratio of the methylmethacrylate (MMA) block in the diblock acrylic-based resin or the triblock acrylic-based resin is in a range from about 30 wt % to about 50 wt %.

In some embodiments, at least one of the first thermoplastic resin layer 20 and the second thermoplastic resin layer 24 contains 0.1% to 10% of light diffusion particles. That is, one of the first thermoplastic resin layer 20 and the second thermoplastic resin layer 24 contains 0.1% to 10% of the light diffusion particles, or both of the first thermoplastic resin layer 20 and the second thermoplastic resin layer 24 contain 0.1% to 10% of the light diffusion particles. In some embodiments, the light diffusion particles may include polyacrylic resin or copolymers derived therefrom, for example, methyl polyacrylate. In some embodiments, the light diffusion particles may be spherical, with a particle size ranging from about 3 μm to about 60 μm, and a refractive index ranging from about 1.45 to about 1.57. The disclosed light diffusion particles can be uniformly dispersed in the thermoplastic resin layer. Specifically, the light diffusion particles are usually added to the thermoplastic resin layer located at a light-incident surface of the module. For example, if the solar cell module 10 is a solar cell module that receives light from one side, the light diffusion particles can be added to the first thermoplastic resin layer 20 or the second thermoplastic resin layer 24 located at the light-incident surface. However, if the solar cell module 10 is a solar cell module that receives light from both sides, the light diffusion particles can be added to the first thermoplastic resin layer 20 and the second thermoplastic resin layer 24 located at the light-incident surfaces at the same time.

In some embodiments, at least one of the first thermoplastic resin layer 20 and the second thermoplastic resin layer 24 contains 0.1% to 5% of fluorescent material. That is, one of the first thermoplastic resin layer 20 and the second thermoplastic resin layer 24 contains 0.1% to 5% of the fluorescent material, or both of the first thermoplastic resin layer 20 and the second thermoplastic resin layer 24 contains 0.1% to 5% of the fluorescent material. In some embodiments, the fluorescent material have the material properties of absorbing ultraviolet light and converting the ultraviolet light into visible light. In some embodiments, the melting point of the fluorescent material is between about 10° C. to about 130° C. The disclosed fluorescent material can be uniformly dispersed in the thermoplastic resin layer. In some embodiments, the fluorescent material may include pyrene, naphthalene-imide, perylene-imide, carbazole or anthracene. Similarly, the fluorescent material is usually added to the thermoplastic resin layer located at a light-incident surface of the module. For example, if the solar cell module 10 is a solar cell module that receives light from one side, the fluorescent material can be added to the first thermoplastic resin layer 20 or the second thermoplastic resin layer 24 located at the light-incident surface. However, if the solar cell module 10 is a solar cell module that receives light from both sides, the fluorescent material can be added to the first thermoplastic resin layer 20 and the second thermoplastic resin layer 24 located at the light-incident surfaces at the same time. The disclosed fluorescent material can absorb an external ultraviolet light and convert the absorbed ultraviolet light into a visible light that can be used by the battery. On the one hand, it can protect the packaging material from ultraviolet light. On the other hand, it can also increase the light absorption of the battery. In addition, the disclosed fluorescent material is an organic fluorescent material, which can be added to the resin layer to obtain a good dispersion effect without increasing the haze, maintaining the transparency of the packaging material.

In some embodiments, if the solar cell module 10 is a solar cell module that receives light from one side, the first thermosetting resin layer 18 or the second thermosetting resin layer 22 located at the light-incident surface of the module may contain 0.1% to 10% of the light diffusion particles. In some embodiments, if the solar cell module 10 is a solar cell module that receives light from both sides, the first thermosetting resin layer 18 and the second thermosetting resin layer 22 located at the light-incident surfaces of the module may contain 0.1% to 10% of the light diffusion particles at the same time. In some embodiments, the light diffusion particles can be uniformly dispersed in the thermosetting resin layer.

In some embodiments, if the solar cell module 10 is a solar cell module that receives light from one side, the first thermosetting resin layer 18 or the second thermosetting resin layer 22 located at the light-incident surface of the module may contain 0.1% to 5% of the fluorescent material. In some embodiments, if the solar cell module 10 is a solar cell module that receives light from both sides, the first thermosetting resin layer 18 and the second thermosetting resin layer 22 located at the light-incident surfaces of the module may contain 0.1% to 5% of the fluorescent material at the same time. In some embodiments, the fluorescent material can be uniformly dispersed in the thermosetting resin layer.

In some embodiments, the glass transition temperature of the first thermoplastic resin layer 20 and the second thermoplastic resin layer 24 is in a range from about 15° C. to about −20° C. In some embodiments, the glass transition temperature of the first thermoplastic resin layer 20 and the second thermoplastic resin layer 24 is in a range from about 10° C. to about −50° C. In some embodiments, the melt flow index of the first thermoplastic resin layer 20 and the second thermoplastic resin layer 24 is in a range from about 1.0 to about 31.0. In some embodiments, the melt flow index of the first thermoplastic resin layer 20 and the second thermoplastic resin layer 24 is in a range from about 1.0 to about 8.0. In some embodiments, the hardness (type A) of the first thermoplastic resin layer 20 and the second thermoplastic resin layer 24 is in a range from about 30 to about 90. In some embodiments, the hardness (type A) of the first thermoplastic resin layer 20 and the second thermoplastic resin layer 24 is in a range from about 35 to about 80.

In the present disclosure, the first thermosetting resin layer 18 and the first thermoplastic resin layer 20 form a transparent composite packaging film by, for example, bonding or co-extrusion. The second thermosetting resin layer 22 and the second thermoplastic resin layer 24 form another transparent composite packaging film by, for example, bonding or co-extrusion.

Specifically, after the disclosed solar cell module 10 is tested for weather resistance, the solar cell module 10 is further disassembled by, for example, a thermal dissociation method or a chemical dissociation method. In some embodiments, in the thermal dissociation method, the solar cell module 10 is disassembled by baking at a temperature of 450° C. In some embodiments, in the chemical dissociation method, the solar cell module 10 is disassembled by soaking in a solvent at a temperature below 40° C. In some embodiments, the solvent used in the chemical dissociation method may include hydrocarbon solvents such as toluene, 2-toluene, hexane, or cyclohexane.

In the disclosed solar cell module, the thermoplastic resin layer is added between the cell unit and the thermosetting resin layer, and its material may include diblock or triblock hydrogenated styrene-based resin, or diblock or triblock acrylic-based resin. The material composition design will enable the cell module to have characteristics of high light transmittance, low water absorption, high insulation and weather resistance, and resistance to PID (Potential Induced Degradation), humidity, heat, and UV, so to meet the needs of cell modules. Also, the cell modules can be easily disassembled and recycled by simple thermal dissociation method or chemical dissociation method, which is not easy to cause fragments, and has the advantage of easy disassembly.

In the disclosed solar cell module, adding a specific content (for example, 0.1% to 10%) of the light diffusion particles to the thermoplastic resin layer can improve the effect of light diffusion of light in the cell (a diffusion factor of 27 or more). The scattering characteristics can improve the light utilization rate of the battery. Even with the addition of the light diffusion particles, the disclosed solar cell module still has optical properties with high light transmittance.

In the present disclosure, in addition to adding a specific content of the light diffusion particles to the thermoplastic resin layer, a specific content (such as 0.1% to 5%) of the fluorescent material can also be added to the thermoplastic resin layer at the same time. In addition to the light diffusion particles that can guide the reflected light of the battery back into the battery, the fluorescent material can also absorb an external ultraviolet light and convert it into a visible light that the battery can use, increasing the amount of light received by the battery. Therefore, when comparing the power gain of the cell module before and after packaging with the conventional cell module, the disclosed solar cell module can obtain a better power gain.

### Preparation Example 1

Preparation of Light Diffusion Composite Film (Containing Light Diffusion Particles)

100 kg of triblock acrylic-based resin (KURARAY, LA2140, melt flow index: 31 g/10 min (190° C., 2.16 kgf)) and 3 kg of light diffusion particles (purchased from Soken Chemical & Engineering Co., Ltd., material: polyacrylic resin, particle size: 10 μm, refractive index: 1.49) were granulated by a single screw mixer (Japan MEISEI KINZOKU MFG. CO., LTD., model: FRP-V32C). The temperature of the single screw mixer at four stages was set at 145° C., 150° C., 150° C. and 145° C. After a press machine (GANG LING MACHINERY CO., LTD., model: HP-50) was preheated at 150° C. for 10 minutes, the sample was compressed at 150° C. for 10 minutes (pressure: 100 kg/cm²) to form a film as a light diffusion composite film.

### Preparation Example 2

Preparation of Light Diffusion Composite Film (Containing Light Diffusion Particles and Fluorescent Material)

100 kg of triblock acrylic-based resin (KURARAY, LA2140, melt flow index: 31 g/10 min (190° C., 2.16 kgf)), 3 kg of light diffusion particles (purchased from Soken Chemical & Engineering Co., Ltd., material: polyacrylic resin, particle size: 10 μm, refractive index: 1.49) and 0.1 kg of carbazole fluorescent material (purchased from NISSOKU TECHNO FINE CHEMICAL CO., LTD.) were granulated by a single screw mixer (Japan MEISEI KINZOKU MFG. CO., LTD., model: FRP-V32C). The temperature of the single screw mixer at four stages was set at 145° C., 150° C., 150° C. and 145° C. After a press machine (GANG LING MACHINERY CO., LTD., model: HP-50) was preheated at 150° C. for 10 minutes, the sample was compressed at 150° C. for 10 minutes (pressure: 100 kg/cm²) to form a thermoplastic film as a light diffusion fluorescent composite film.

### Example 1

The Physical Property Test of the Solar Cell Module (the Thermoplastic Resin Layer Including Triblock Acrylic-Based Resin and Light Diffusion Particles)

In this example, the physical property tests were performed on the solar cell module 10 as shown in FIG. 1. In the module structure, the materials and dimensions of related components are described below: The first substrate (back plate) 12 was a solar back plate with a thickness of about 0.31 mm. The second substrate (front plate) 14 was transparent glass with a thickness of about 3.2 mm. The thickness of the cell unit 16 was about 180 μm. The first thermosetting resin layer 18 was an ethylene vinyl acetate (EVA) copolymer (SKC, EF2N) with a thickness of about 400 μm. The first thermoplastic resin layer 20 with a thickness of about 292 μm included triblock acrylic-based resin (KURARAY, LA2140, melt flow index: 31 g/10 min (190° C., 2.16 kgf)) and 3% of light diffusion microspheres (purchased from Soken Chemical & Engineering Co., Ltd., material: polyacrylic resin, particle size: 10 μm, refractive index: 1.49). The second thermosetting resin layer 22 was an ethylene vinyl acetate (EVA) copolymer (SKC, EF2N) with a thickness of about 400 μm. The second thermoplastic resin layer 24 with a thickness of about 292 μm included triblock acrylic-based resin (KURARAY, LA2140, melt flow index: 31 g/10 min (190° C., 2.16 kgf)) and 3% of light diffusion microspheres (purchased from Soken Chemical & Engineering Co., Ltd., material: polyacrylic resin, particle size: 10 μm, refractive index: 1.49). The total thickness T1 of the first thermosetting resin layer 18 and the first thermoplastic resin layer 20 was approximately 692±3 μm. The total thickness T2 of the second thermosetting resin layer 22 and the second thermoplastic resin layer 24 was approximately 692±3 μm. The following physical property tests were performed on the solar cell module 10, including haze (%), total light transmittance (%) and diffusion factor, and the test results are shown in Table 1. In addition, the solar cell module 10 was tested for power gain (%) before and after packaging. The test results are shown in Table 2 below. The test method for light transmittance measurement was ASTM D1003. The test method for haze measurement was ASTM D1003. The test method for maximum power measurement was IEC60891. The test method for short-circuit current measurement was IEC60891. The test method for open-circuit voltage measurement was IEC60891.

### Example 2

The Physical Property Test of the Solar Cell Module (the Thermoplastic Resin Layer Including Triblock Acrylic-Based Resin, Light Diffusion Particles and Fluorescent Material)

In this example, the physical property tests were performed on the solar cell module 10 as shown in FIG. 1. In the module structure, the materials and dimensions of related components are described below: The first substrate (back plate) 12 was a solar back plate with a thickness of about 0.31 mm. The second substrate (front plate) 14 was transparent glass with a thickness of about 3.2 mm. The thickness of the cell unit 16 was about 180 μm. The first thermosetting resin layer 18 was an ethylene vinyl acetate (EVA) copolymer (SKC, EF2N) with a thickness of about 400 μm. The first thermoplastic resin layer 20 with a thickness of about 292 μm included triblock acrylic-based resin (KURARAY, LA2140, melt flow index: 31 g/10 min (190, 2.16 kgf)), 3% of light diffusion microspheres (purchased from Soken Chemical & Engineering Co., Ltd., material: polyacrylic resin, particle size: 10 μm, refractive index: 1.49) and 0.1% of carbazole fluorescent material (purchased from NISSOKU TECHNO FINE CHEMICAL CO., LTD., melting point: 80° C.). The second thermosetting resin layer 22 was an ethylene vinyl acetate (EVA) copolymer (SKC, EF2N) with a thickness of about 400 μm. The second thermoplastic resin layer 24 with a thickness of about 292 μm included triblock acrylic-based resin (KURARAY, LA2140, melt flow index: 31 g/10 min (190° C., 2.16 kgf)), 3% of light diffusion microspheres (purchased from Soken Chemical & Engineering Co., Ltd., material: polyacrylic resin, particle size: 10 μm, refractive index: 1.49) and 0.1% of carbazole fluorescent material (purchased from NISSOKU TECHNO FINE CHEMICAL CO., LTD., melting point: 80° C.). The total thickness T1 of the first thermosetting resin layer 18 and the first thermoplastic resin layer 20 was approximately 692±3 μm. The total thickness T2 of the second thermosetting resin layer 22 and the second thermoplastic resin layer 24 was approximately 692±3 μm. The following physical property tests were performed on the solar cell module 10, including haze (%), total light transmittance (%) and diffusion factor, and the test results are shown in Table 1. In addition, the solar cell module 10 was tested for power gain (%) before and after packaging. The test results are shown in Table 2 below.

### Comparative Example 1

The Physical Property Test of the Solar Cell Module (the Thermoplastic Resin Layer Including Triblock Acrylic-Based Resin without Light Diffusion Particles or Fluorescent Material)

In this comparative example, the physical property tests were performed on the solar cell module 10 as shown in FIG. 1. In the module structure, the materials and dimensions of related components are described below: The first substrate (back plate) 12 was a solar back plate with a thickness of about 0.31 mm. The second substrate (front plate) 14 was transparent glass with a thickness of about 3.2 mm. The thickness of the cell unit 16 was about 180 μm. The first thermosetting resin layer 18 was an ethylene vinyl acetate (EVA) copolymer (SKC, EF2N) with a thickness of about 400 μm. The first thermoplastic resin layer 20 with a thickness of about 292 μm included triblock acrylic-based resin (KURARAY, LA2140, melt flow index: 31 g/10 min (190, 2.16 kgf)). The second thermosetting resin layer 22 was an ethylene vinyl acetate (EVA) copolymer (SKC, EF2N) with a thickness of about 400 μm. The second thermoplastic resin layer 24 with a thickness of about 292 μm included triblock acrylic-based resin (KURARAY, LA2140, melt flow index: 31 g/10 min (190° C., 2.16 kgf)). The total thickness T1 of the first thermosetting resin layer 18 and the first thermoplastic resin layer 20 was approximately 692±3 μm. The total thickness T2 of the second thermosetting resin layer 22 and the second thermoplastic resin layer 24 was approximately 692±3 μm. The following physical property tests were performed on the solar cell module 10, including haze (%), total light transmittance (%) and diffusion factor, and the test results are shown in Table 1. In addition, the solar cell module 10 was tested for power gain (%) before and after packaging. The test results are shown in Table 2 below.

### Comparative Example 2

The Physical Property Test of the Solar Cell Module (Only EVA Package)

In this comparative example, the physical property tests were performed on the specific solar cell module (the thermosetting resin layer was in contact with the cell unit and the substrate simultaneously). In the module structure, the materials and dimensions of related components are described below: The first substrate (back plate) was a solar back plate with a thickness of about 0.31 mm. The second substrate (front plate) was transparent glass with a thickness of about 3.2 mm. The thickness of the cell unit was about 180 μm. The first thermosetting resin layer was an ethylene vinyl acetate (EVA) copolymer (SKC, EF2N) with a thickness of about 400 μm. The second thermosetting resin layer was an ethylene vinyl acetate (EVA) copolymer (SKC, EF2N) with a thickness of about 400 μm. The following physical property tests were performed on the solar cell module 10, including haze (%), total light transmittance (%) and diffusion factor, and the test results are shown in Table 1. In addition, the solar cell module 10 was tested for power gain (%) before and after packaging. The test results are shown in Table 2 below.

### Comparative Example 3

The Physical Property Test of the Solar Cell Module (Light Guide Bar and Eva Package)

In this comparative example, the physical property tests were performed on the specific solar cell module (the thermosetting resin layer was in contact with the cell unit and the substrate simultaneously). In the module structure, the materials and dimensions of related components are described below: The first substrate (back plate) was a solar back plate with a thickness of about 0.31 mm. The second substrate (front plate) was transparent glass with a thickness of about 3.2 mm. The thickness of the cell unit (a light guide bar was pasted on the surface of the cell unit) was about 180 μm. The first thermosetting resin layer was an ethylene vinyl acetate (EVA) copolymer (SKC, EF2N) with a thickness of about 400 μm. The second thermosetting resin layer was an ethylene vinyl acetate (EVA) copolymer (SKC, EF2N) with a thickness of about 400 μm. The following physical property tests were performed on the solar cell module 10, including haze (%), total light transmittance (%) and diffusion factor, and the test results are shown in Table 1. In addition, the solar cell module 10 was tested for power gain (%) before and after packaging. The test results are shown in Table 2 below.

### Comparative Example 4

The Physical Property Test of the Solar Cell Module (EVA Package and Light Diffusion Particles)

In this comparative example, the physical property tests were performed on the specific solar cell module (the thermosetting resin layer was in contact with the cell unit and the substrate simultaneously). In the module structure, the materials and dimensions of related components are described below: The first substrate (back plate) was a solar back plate with a thickness of about 0.31 mm. The second substrate (front plate) was transparent glass with a thickness of about 3.2 mm. The thickness of the cell unit was about 180 μm. The first thermosetting resin layer with a thickness of about 400 μm included an ethylene vinyl acetate (EVA) copolymer (SKC, EF2N) and 3% of light diffusion microspheres (purchased from Soken Chemical & Engineering Co., Ltd., material: polyacrylic resin, particle size: 10 μm, refractive index: 1.49). The second thermosetting resin layer with a thickness of about 400 μm included an ethylene vinyl acetate (EVA) copolymer (SKC, EF2N) and 3% of light diffusion microspheres (purchased from Soken Chemical & Engineering Co., Ltd., material: polyacrylic resin, particle size: 10 μm, refractive index: 1.49). The following physical property tests were performed on the solar cell module 10, including haze (%), total light transmittance (%) and diffusion factor, and the test results are shown in Table 1. In addition, the solar cell module 10 was tested for power gain (%) before and after packaging. The test results are shown in Table 2 below.

TABLE 1

| | Example | Example | Com. Example | Com. Example | Com. Example | Com. Example |
|---|---|---|---|---|---|---|
| | 1 | 2 | 1 | 2 | 3 | 4 |
| Module | Composite | Composite | Composite | EVA film/ | EVA film/ | EVA film/ |
| | film/ | film/ | film/ | cell unit | cell unit | cell unit |
| | cell unit | cell unit | cell unit | | (with light | |
| | | | | | guide bar) | |
| Composition of | EVA | EVA | EVA | EVA | EVA | EVA |
| packaging film | thermosetting | thermosetting | thermosetting | thermosetting | thermosetting | thermosetting |
| | film/ | film/ | film/ | film | film | film/ |
| | triblock | triblock | triblock | | | diffusion |
| | acrylic-based | acrylic-based | acrylic-based | | | particles |
| | resin film/ | resin film/ | resin film | | | |
| | diffusion | diffusion | | | | |
| | particles | particles/ | | | | |
| | | fluorescent | | | | |
| | | material | | | | |
| Haze (%) | 28.8 | 28.5 | 1.9 | 1.4 | 1.4 | 12.56 |
| Total light | 94.7 | 96.0 | 96.6 | 97.6 | 97.6 | 97.04 |
| transmittance | | | | | | |
| (%) | | | | | | |
| Diffusion factor | 27.3 | 27.4 | 1.9 | 1.4 | 1.4 | 12.19 |

TABLE 2

| | Example | Example | Com. Example | Com. Example | Com. Example | Com. Example |
|---|---|---|---|---|---|---|
| | 1 | 2 | 1 | 2 | 3 | 4 |
| Module | Composite | Composite | Composite | EVA film/ | EVA film/ | EVA film/ |
| | film/ | film/ | film/ | cell unit | cell unit | cell unit |
| | cell unit | cell unit | cell unit | | (with light | |
| | | | | | guide bar) | |
| Composition of | EVA | EVA | EVA | EVA | EVA | EVA |
| packaging film | thermosetting | thermosetting | thermosetting | thermosetting | thermosetting | thermosetting |
| | film/ | film/ | film/ | film | film | film/ |
| | triblock | triblock | triblock | | | diffusion |
| | acrylic-based | acrylic-based | acrylic-based | | | particles |
| | resin film/ | resin film/ | resin film | | | |
| | diffusion | diffusion | | | | |
| | particles | particles/ | | | | |
| | | fluorescent | | | | |
| | | material | | | | |
| Before | 12.359 | 11.933 | 12.167 | 13.035 | 12.525 | 13.024 |
| packaging | | | | | | |
| After | 17.36 | 16.096 | 16.167 | 17.259 | 17.22 | 14.67 |
| packaging | | | | | | |
| Power gain | 40.46 | 34.89 | 32.88 | 32.41 | 37.49 | 12.64 |
| (%) | | | | | | |

From the test results in Table 1, it can be seen that, in the disclosed solar cell modules (such as Examples 1 and 2), the light diffusion particles with the specific content were added to the thermoplastic resin layer. Therefore, the effect of light diffusion of light in the battery can be greatly improved indeed (the diffusion factor was as high as 27 or more). Also, according to the measured haze, total light transmittance and other data, the disclosed solar cell modules still have optical characteristics of high light transmittance.

From the test results in Table 2, it can be seen that, in the disclosed solar cell modules, the light diffusion particles with the specific content were added to the thermoplastic resin layer (such as Example 1). The light diffusion particles and the fluorescent material with the specific contents respectively were added to the thermoplastic resin layer at the same time (such as Example 2). The light diffusion particles can guide the reflected light of the battery back into the battery, and the fluorescent material can absorb an external ultraviolet light and convert it into a visible light that the battery can use, so that the amount of light received by the battery was increased. Therefore, when comparing the power gain of the cell modules before and after packaging with the cell modules provided by Comparative Examples 1-3, the disclosed solar cell modules can obtain a better power gain.

The present disclosure provides a composite packaging film composed of a thermosetting resin layer (such as EVA) and a thermoplastic resin layer (such as SEBS). In addition to protecting the module to have a long life, when the module is disassembled, due to the thermoplastic characteristics, the molten packaging film can be separated from the glass and the complete battery at an appropriate temperature, which is beneficial to the subsequent high-value recycling.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A solar cell module, comprising:
a first substrate;
a second substrate opposite to the first substrate;
a cell unit disposed between the first substrate and the second substrate;
a first thermosetting resin layer disposed between the cell unit and the first substrate;
a first thermoplastic resin layer disposed between the cell unit and the first thermosetting resin layer;
a second thermosetting resin layer disposed between the cell unit and the second substrate; and
a second thermoplastic resin layer disposed between the cell unit and the second thermosetting resin layer, wherein at least one of the first thermoplastic resin layer and the second thermoplastic resin layer contains 0.1% to 10% of light diffusion particles.

2. The solar cell module as claimed in claim 1, wherein the first substrate and the second substrate comprise glass, polyolefin resin or polyester resin.

3. The solar cell module as claimed in claim 1, wherein the first thermoplastic resin layer and the second thermoplastic resin layer comprise diblock hydrogenated styrene-based resin, triblock hydrogenated styrene-based resin, diblock acrylic-based resin or triblock acrylic-based resin.

4. The solar cell module as claimed in claim 1, wherein the light diffusion particles comprise polyacrylic resin or copolymers derived therefrom.

5. The solar cell module as claimed in claim 4, wherein the light diffusion particles are spherical, with a particle size ranging from 3 μm to 60 μm, and a refractive index ranging from 1.45 to 1.57.

6. The solar cell module as claimed in claim 1, wherein the first thermosetting resin layer or the second thermosetting resin layer contains 0.1% to 10% of the light diffusion particles.

7. The solar cell module as claimed in claim 1, wherein at least one of the first thermoplastic resin layer and the second thermoplastic resin layer further contains 0.1% to 5% of fluorescent material.

8. The solar cell module as claimed in claim 7, wherein the fluorescent material absorbs an ultraviolet light and converts the ultraviolet light into a visible light.

9. The solar cell module as claimed in claim 7, wherein the fluorescent material comprises pyrene, naphthalene-imide, perylene-imide, carbazole or anthracene.

10. The solar cell module as claimed in claim 1, wherein the first thermosetting resin layer or the second thermosetting resin layer contains 0.1% to 5% of fluorescent material.
